(19) United States
(12) Patent Application Publication
(10) Pub. No.: US 2025/0120271 A1
(43) Pub. Date: Apr. 10, 2025

(54) DISPLAY PANEL, PREPARATION METHOD THEREFOR, AND DISPLAY APPARATUS

(71) Applicants: Chongqing BOE Display Technology Co.,Ltd., Chongqing (CN); BOE Technology Group Co., Ltd., Beijing (CN)

(72) Inventors: Yuxuan PAN, Beijing (CN); Yu TIAN, Beijing (CN); Pei WANG, Beijing (CN); Kai ZHANG, Beijing (CN)

(21) Appl. No.: 18/833,937

(22) PCT Filed: Oct. 9, 2023
(86) PCT No.: PCT/CN2023/123568

§ 371 Date: Jul. 29, 2024

(30) Foreign Application Priority Data
Nov. 22, 2022 (CN) 202211465841.0

(51) Int. Cl. H10K 59/131; G06F 3/041; G06F 3/044; G09G 3/3233; H10K 59/12; H10K 59/40

(52) U.S. Cl. CPC H10K 59/131; G06F 3/0412; G06F 3/04164; G06F 3/0446; H10K 59/1201; H10K 59/40; G06F 2203/04112; G09G 3/3233; G09G 2300/0819; G09G 2300/0842; G09G 2300/0861; G09G 2310/08; G09G 2354/00

(57) ABSTRACT

Disclosed is a display panel, which comprises: a base substrate, and, disposed on the base substrate, a circuit structure layer and a light-emitting structure layer. The base substrate comprises a first display area, and a second display area located on at least one side of the first display area. The circuit structure layer comprises a plurality of first pixel circuits and a plurality of second pixel circuits which are located in the second display area, and a plurality of connecting lines extending from the second display area to the first display area. The light-emitting structure layer comprises a plurality of first light-emitting elements located in the first display area, and a plurality of second light-emitting elements located in the second display area. At least one first pixel circuit is electrically connected to at least one first light-emitting element by means of at least one connection line.

### CROSS-REFERENCE TO RELATED APPLICATIONS

The present application is a U.S. National Phase Entry of International Application No. PCT/CN2023/123568 having an international filing date of Oct. 9, 2023, which claims priority to application No. 202211465841.0 filed to the CNIPA on Nov. 22, 2022, the contents of the above-identified applications should be construed as being incorporated into the present application by reference.

### TECHNICAL FIELD

The present disclosure relates to, but is not limited to, the field of display technologies, and particularly to a display panel, a preparation method therefor, and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc. With continuous development of display technologies, a camera is usually installed on a display device to meet shooting needs.

### SUMMARY

The following is a summary of subject matters described herein in detail. This summary is not intended to limit the protection scope of claims.

Embodiments of the present disclosure provide a display panel, a preparation method therefor, and a display apparatus.

In one aspect, an embodiment of the present disclosure provides a display panel, including a base substrate, a circuit structure layer, and a light emitting structure layer. The base substrate includes a first display area and a second display area located on at least one side of the first display area. The circuit structure layer is located on the base substrate and includes a plurality of first pixel circuits and a plurality of second pixel circuits which are located in the second display area, and a plurality of connecting lines extending from the second display area to the first display area. The light emitting structure layer is located on a side of the circuit structure layer away from the base substrate, and includes a plurality of first light emitting elements located in the first display area and a plurality of second light emitting elements located in the second display area. At least one first pixel circuit among the plurality of first pixel circuits is electrically connected with at least one first light emitting element among the plurality of first light emitting elements by means of at least one of the plurality of connecting lines, and is configured to drive the at least one first light emitting element to emit light. At least one second pixel circuit among the plurality of second pixel circuits is electrically connected with at least one second light emitting element among the plurality of second light emitting elements, and is configured to drive the at least one second light emitting element to emit light. An orthographic projection of the plurality of connecting lines on the base substrate is not overlapped with an orthographic projection of anodes of the plurality of second light emitting elements on the base substrate.

In some exemplary embodiments, an orthographic projection of the plurality of first pixel circuits on the base substrate is not overlapped with an orthographic projection of the plurality of first light emitting elements on the base substrate.

In some exemplary embodiments, the orthographic projection of the plurality of connecting lines on the base substrate is a mesh pattern.

In some exemplary embodiments, the plurality of connecting lines are made of a transparent conductive material.

In some exemplary embodiments, in the second display area, the plurality of first pixel circuits are located on a side of the plurality of second pixel circuits away from the first display area.

In some exemplary embodiments, the second display area is located on at least one side of the first display area along a first direction, and the plurality of first pixel circuits are located on a side of the plurality of second pixel circuits away from the first display area along the first direction.

In some exemplary embodiments, the plurality of first pixel circuits are distributed at intervals among the plurality of second pixel circuits.

In some exemplary embodiments, an orthographic projection of an anode of the at least one second light emitting element on the base substrate is overlapped with an orthographic projection of a second pixel circuit connected thereto on the base substrate.

In some exemplary embodiments, in a direction perpendicular to the display panel, the circuit structure layer includes a semiconductor layer, a first conductive layer, a second conductive layer, a third conductive layer, and a fourth conductive layer which are sequentially provided on the base substrate. The plurality of connecting lines are located on the third conductive layer.

In some exemplary embodiments, the plurality of first pixel circuits are located on a side of the plurality of second pixel circuits away from the first display area along the first direction. The fourth conductive layer includes a signal line extending along a second direction. The first direction intersects with the second direction.

In some exemplary embodiments, the signal line of the fourth conductive layer includes a plurality of power supply connection segments extending along the second direction. The third conductive layer includes a power supply lap island. Adjacent power supply connection segments are electrically connected by means of the power supply lap island.

In some exemplary embodiments, the semiconductor layer includes active layers of transistors of the plurality of first pixel circuits and the plurality of second pixel circuits. The first conductive layer includes gates of the transistors, and first capacitance electrode plates of storage capacitors of the plurality of first pixel circuits and the plurality of second pixel circuits. The second conductive layer includes second capacitance electrode plates of the storage capacitors of the plurality of first pixel circuits and the plurality of second pixel circuits. The third conductive layer includes a plurality of lap islands configured to realize electrical connections between the transistors and electrical connections between the transistors and a signal line extending along the first direction.

In some exemplary embodiments, the display panel further includes an encapsulation structure layer located on a side of the light emitting structure layer away from the base substrate and a touch structure layer located on a side of the encapsulation structure layer away from the base substrate. The touch structure layer includes a plurality of touch electrodes, and the plurality of touch electrodes include a metal mesh pattern. An orthographic projection of the metal mesh pattern of the touch structure layer on the base substrate covers the orthographic projection of the plurality of connecting lines on the base substrate.

In some exemplary embodiments, the orthographic projection of the plurality of connecting lines on the base substrate is not overlapped with an orthographic projection of an anode of an unconnected first light emitting element on the base substrate.

In another aspect, an embodiment of the present disclosure provides a display apparatus including the aforementioned display panel.

In still another aspect, an embodiment of the present disclosure provides a preparation method of a display panel, which is used for preparing the display panel as described above. The preparation method includes: preparing a circuit structure layer on a base substrate, the circuit structure layer including a plurality of first pixel circuits and a plurality of second pixel circuits which are located in a second display area, and a plurality of connecting lines extending from the second display area to a first display area, the second display area being located on at least one side of the first display area; and preparing a light emitting structure layer on a side of the circuit structure layer away from the base substrate, the light emitting structure layer including a plurality of first light emitting elements located in the first display area and a plurality of second light emitting elements located in the second display area. At least one first pixel circuit among the plurality of first pixel circuits is electrically connected with at least one first light emitting element among the plurality of first light emitting elements by means of at least one of the plurality of connecting lines, and is configured to drive the at least one first light emitting element to emit light. At least one second pixel circuit among the plurality of second pixel circuits is electrically connected with at least one second light emitting element among the plurality of second light emitting elements, and is configured to drive the at least one second light emitting element to emit light. An orthographic projection of the plurality of connecting lines on the base substrate is not overlapped with an orthographic projection of anodes of the plurality of second light emitting elements on the base substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display panel according to at least one embodiment of the present disclosure.

FIG. 2 is an equivalent circuit diagram of a pixel circuit according to at least one embodiment of the present disclosure.

FIG. 3 is a working timing diagram of the pixel circuit provided in FIG. 2.

FIG. 4 is a partial schematic diagram of a display panel according to at least one embodiment of the present disclosure.

FIG. 5 is a plan schematic diagram of a first pixel circuit according to at least one embodiment of the present disclosure.

FIG. 6 is a schematic partial cross-sectional view along a Q-Q′ direction in FIG. 5.

FIG. 7 is a partial schematic diagram of a second display area after a semiconductor layer is formed in FIG. 5.

FIG. 8 is a partial schematic diagram of a second display area after a first conductive layer is formed in FIG. 5.

FIG. 9 is a partial schematic diagram of a second display area after a second conductive layer is formed in FIG. 5.

FIG. 10 is a partial schematic diagram of a second display area after a third insulation layer is formed in FIG. 5.

FIG. 11 is a partial schematic diagram of a second display area after the third conductive layer is formed in FIG. 5.

FIG. 12 is a partial schematic diagram of a second display area after a fourth insulation layer is formed in FIG. 5.

FIG. 13 is a schematic diagram showing extension of a connecting line according to at least one embodiment of the present disclosure.

FIG. 14 is a schematic diagram of architecture of a touch structure layer according to at least one embodiment of the present disclosure.

FIG. 15 is a schematic structural diagram of touch electrodes in a form of a metal mesh according to at least one embodiment of the present disclosure.

FIG. 16 is another partial schematic diagram of a display panel according to at least one embodiment of the present disclosure.

FIG. 17 is a schematic diagram of a display apparatus according to at least one embodiment of the present disclosure.

### DETAILED DESCRIPTION

The embodiments of the present disclosure will be described below with reference to the drawings in detail. Implementation modes may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain electrode and a second electrode may be a source electrode, or, a first electrode may be a source electrode and a second electrode may be a drain electrode. In a case that transistors with opposite polarities are used, or in a case that a direction of a current is changed during working of a circuit, or the like, functions of the “source electrode” and the “drain electrode” are sometimes interchangeable. Therefore, the “source electrode” and the “drain electrode” are interchangeable in the specification.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present specification, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. “A extends in a B direction” in the present specification always means “a main portion of A extends in a B direction”.

With development of display technologies, existing designs of a bangs or water drop screen are gradually unable to meet a user's demand for a high screen-to-body ratio of a display apparatus, and a series of display apparatuses with a light-transmitting display area have emerged as the times require. In this type of display apparatus, hardware such as an optical sensor (for example, a camera) may be disposed in the light-transmitting display area. Since there is no need to punch a hole, under a premise of ensuring practicability of the display apparatus, it is possible to achieve a true full screen. However, the current full-screen products have problems such as complex preparation process, long average preparation time required by product processing procedure, and high production cost.

An embodiment provides a display panel, including a base substrate, a circuit structure layer and a light emitting structure layer which are provided on the base substrate. The base substrate includes a first display area and a second display area located on at least one side of the first display area. The circuit structure layer includes a plurality of first pixel circuits and a plurality of second pixel circuits which are located in the second display area, and a plurality of connecting lines extending from the second display area to the first display area. The light emitting structure layer includes a plurality of first light emitting elements located in the first display area, and a plurality of second light emitting elements located in the second display area. At least one first pixel circuit among the plurality of first pixel circuits is electrically connected with at least one first light emitting element among the plurality of first light emitting elements by means of at least one connecting line, and is configured to drive the at least one first light emitting element to emit light. At least one second pixel circuit among the plurality of second pixel circuits is electrically connected with at least one second light emitting element among the plurality of second light emitting elements, and is configured to drive the at least one second light emitting element to emit light. An orthographic projection of the plurality of connecting lines on the base substrate is not overlapped with an orthographic projection of anodes of the plurality of second light emitting elements on the base substrate.

By providing a plurality of connecting lines located on the circuit structure layer and bypassing anode arrangement of the second light emitting element, the display panel provided by the present embodiment may satisfy the circuit design of the display panel without adding a preparation process and without damaging the display effect of the display panel, thereby realizing a full-screen display.

In some exemplary embodiments, the orthographic projection of the plurality of connecting lines on the base substrate may form a mesh pattern. In the present example, the connecting lines bypass the anodes of the second light emitting elements, so that through hole in the area where the second pixel circuit is located may be avoided as much as possible, and a molar pattern that may be caused by the straight line routing may be avoided, thereby improving the display effect of the display panel.

In some exemplary embodiments, the plurality of connecting lines may be made of a transparent conductive material. In the present example, the plurality of connecting lines are made of a transparent conductive material, so as to ensure the light transmittance of the display panel.

In some exemplary embodiments, in the second display area, the plurality of first pixel circuits may be located on a side of the plurality of second pixel circuits away from the first display area. For example, the second display area may be located on at least one side of the first display area along a first direction and the plurality of first pixel circuits may be located on a side of the plurality of second pixel circuits away from the first display area along the first direction. In the present example, by providing the first pixel circuits on a side of the second pixel circuits away from the first display area, it is possible to avoid compressing the second pixel circuits to arrange the first pixel circuits, to avoid changing the arrangement mode and size of the second pixel circuits, and to avoid adding redundant pixel circuits, thereby improving the reliability and display effect of the display panel.

In some exemplary embodiments, in a direction perpendicular to the display panel, the circuit structure layer may include a semiconductor layer, a first conductive layer, a second conductive layer, a third conductive layer, and a fourth conductive layer which are sequentially provided on the base substrate. The plurality of connecting lines may be located on the third conductive layer. In the present example, by providing the connecting lines on the third conductive layer, there is no need to separately provide a film layer where the connecting lines are located, which may reduce the film layer preparation process, reduce the complexity of the preparation process, reduce the average preparation time required by the product processing procedure, improve the design compatibility of the display panel, and reduce the preparation cost.

Schemes of the embodiments will be described below through some examples.

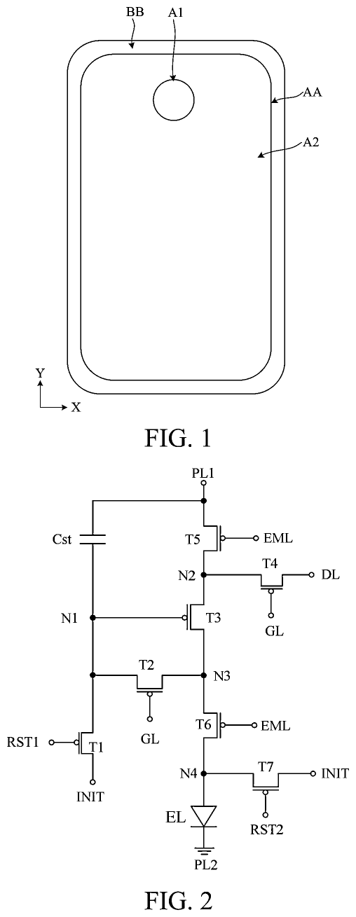

FIG. 1 is a schematic diagram of a display panel according to at least one embodiment of the present disclosure. In some examples, as shown in FIG. 1, the display panel may include a display region AA, and a peripheral region BB surrounding a periphery of the display region AA. The display region AA of the display panel may include a first display area A1 and a second display area A2 located on at least one side of the first display area A1. For example, the second display area A2 may surround the first display area A1. The first display area A1 may be located at a top middle position of the display region AA. However, the present embodiment is not limited thereto. For example, the first display area A1 may be located at another position such as an upper left corner or an upper right corner of the display region AA.

In some examples, as shown in FIG. 1, the display region AA may be in a shape of a rectangle, e.g., a rounded rectangle. The first display area A1 may be circular or elliptical. However, the present embodiment is not limited thereto. For example, the first display area A1 may be rectangular, pentagonal, hexagonal or in another shape.

In some examples, as shown in FIG. 1, the first display area A1 may be a light transmitting display area and may also be referred to as a Full Display with Camera (FDC) area. The second display area A2 may be a non-light transmitting display area, and may also be referred to as a normal display area. A light transmittance rate of the first display area A1 may be greater than a light transmittance rate of the second display area A2. For example, an orthographic projection of hardware such as a photosensitive sensor (such as a camera and, an infrared sensor) on the display panel may be located within the first display area A1 of the display panel. In some examples, the first display area A1 may be circular, and a size of the orthographic projection of the photosensitive sensor on the display panel may be less than or equal to a size of the first display area A1. However, the present embodiment is not limited thereto. In some other examples, the first display area may be rectangular, and the size of the orthographic projection of the photosensitive sensor on the display panel may be less than or equal to a size of an inscribed circle of the first display area.

In some examples, as shown in FIG. 1, a resolution of the second display area A2 may be substantially the same as a resolution of the first display area A1. However, the present embodiment is not limited thereto. In some examples, a ratio of the resolution of the second display area A2 to the resolution of the first display area A1 may be about 0.8 to 1.2.

In some examples, the display region AA may at least include a plurality of regularly arranged pixel units, a plurality of first signal lines (for example, including a scan line, a reset control line, and a light emitting control line) extending along a first direction X, a plurality of second signal lines (for example, including a data line, and a power supply line) extending along a second direction Y. The first direction X and the second direction Y may be located in a same plane, and the first direction X intersects with the second direction Y, for example, the first direction X may be perpendicular to the second direction Y.

In some examples, one pixel unit of the display region AA may include three sub-pixels, which may be a red sub-pixel, a green sub-pixel, and a blue sub-pixel, respectively. However, the present embodiment is not limited thereto. In some examples, one pixel unit may include four sub-pixels, which may be a red sub-pixel, a green sub-pixel, a blue sub-pixel, and a white sub-pixel, respectively.

In some examples, at least one sub-pixel may include a pixel circuit and a light emitting element. The pixel circuit may be configured to drive a light emitting element connected thereto. For example, the pixel circuit may be configured to provide a driving current for driving the light emitting element to emit light. The pixel circuit may include a plurality of transistors and at least one capacitor. For example, the pixel circuit may be of a 3TIC structure, an 8TIC structure, a 7TIC structure, or a 5TIC structure. In the above circuit structure, T refers to a thin film transistor, C refers to a capacitor, a number before T represents a quantity of thin film transistors in the circuit, and a number before C represents a quantity of capacitors in the circuit.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, white light or the like under drive of a pixel circuit corresponding to the light emitting element. A color of light emitted from the light emitting element may be determined as required. In some examples, the light emitting element may include an anode, a cathode, and an organic light emitting layer located between the anode and the cathode. The anode of the light emitting element may be electrically connected with a corresponding pixel circuit. However, the present embodiment is not limited thereto.

In some examples, a shape of the light emitting element may be a rectangle, a rhombus, a pentagon, or a hexagon. When one pixel unit includes three sub-pixels, light emitting elements of the three sub-pixels may be arranged side by side horizontally, side by side vertically, or in a delta arrangement. When one pixel unit includes four sub-pixels, light emitting elements of the four sub-pixels may be arranged side by side horizontally, side by side vertically, or in a shape of a square. However, the present embodiment is not limited thereto.

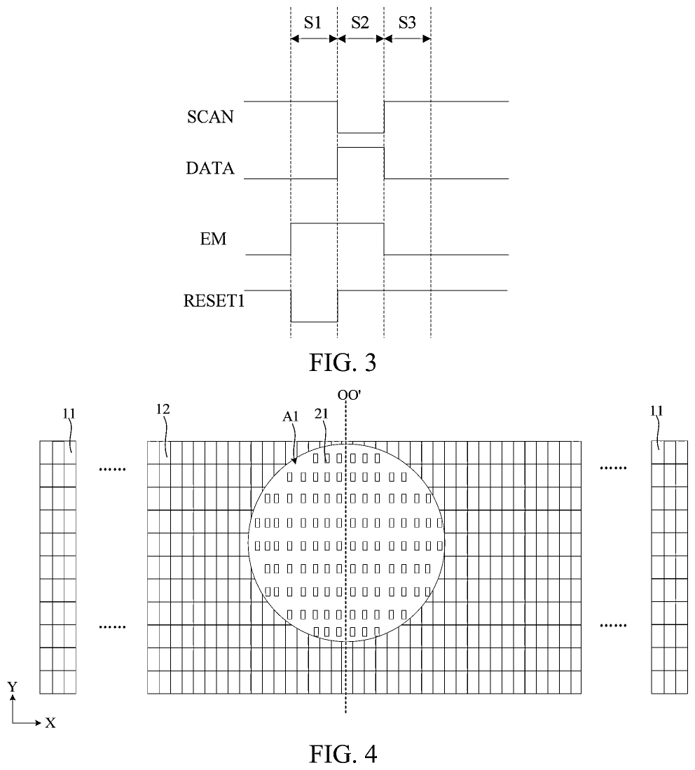

FIG. 2 is an equivalent circuit diagram of a pixel circuit according to at least one embodiment of the present disclosure. The pixel circuit of the present example is described by taking a 7TIC structure as an example. FIG. 3 is a working timing diagram of the pixel circuit provided in FIG. 2.

In some examples, as shown in FIG. 2, the pixel circuit of the present example may include six switching transistors (T1, T2, and T4 to T7), one drive transistor T3, and one storage capacitor Cst. The six switching transistors are respectively a data writing transistor T4, a threshold compensation transistor T2, a first light emitting control transistor T5, a second light emitting control transistor T6, a first reset transistor T1, and a second reset transistor T7. A light emitting element EL may include an anode, a cathode, and an organic light emitting layer provided between the anode and the cathode.

In some examples, the drive transistor and the six switching transistors may be P-type transistors or may be N-type transistors. Adopting a same type of transistors in the pixel circuit may simplify a process flow, reduce process difficulties of the display panel, and improve a yield of products. In some possible implementations, the drive transistor and the six switching transistors may include a P-type transistor and an N-type transistor.

In some examples, the drive transistor and the six switching transistors may employ low temperature poly silicon thin film transistors, or employ oxide thin film transistors, or employ both low temperature poly silicon thin film transistors and oxide thin film transistors. An active layer of the low temperature poly silicon thin film transistor is made of Low Temperature Poly Silicon (LTPS), and an active layer of the oxide thin film transistor is made of an oxide semiconductor (Oxide). The low temperature poly silicon thin film transistor has advantages, such as a high mobility, and fast charging, etc., while the oxide thin film transistor has advantages, such as a low leakage current, etc. The low temperature poly silicon thin film transistor and the oxide thin film transistor are integrated on one display panel to form a low temperature poly silicon oxide (LTPS+Oxide) display panel, and advantages of both the low temperature poly silicon thin film transistor and the oxide thin film transistor may be utilized, which may achieve low frequency drive, reduce power consumption, and improve display quality.

In some examples, as shown in FIG. 2, a pixel circuit may be connected with a scan line GL, a data line DL, a first power supply line PL1, a second power supply line PL2, a light emitting control line EML, an initial signal line INIT, a first reset control line RST1, and a second reset control line RST2. In some examples, the first power supply line PL1 may be configured to provide a constant first voltage signal VDD to a pixel circuit, the second power supply line PL2 may be configured to provide a constant second voltage signal VSS to a pixel circuit, and the first voltage signal VDD is greater than the second voltage signal VSS. The scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the first reset control line RST1 may be configured to provide a first reset control signal RESET1 to the pixel circuit, and the second reset control line RST2 may be configured to provide a second reset signal RESET2 to the pixel circuit.

In some examples, in a row of pixel circuits, a second reset control line RST2 may be connected with a scan line GL to be input with a scan signal SCAN. That is, a second reset signal RESET2(n) received by a pixel circuit of an n-th row is a scan signal SCAN(n) received by the pixel circuit of the n-th row, where n is a positive integer. However, the present embodiment is not limited thereto. For example, the second reset control signal line RST2 may be input with a second reset control signal RESET2 different from the scan signal SCAN. In some examples, in a pixel circuit of an n-th row, a first reset control line RST1 may be connected with a scan line GL of a pixel circuit of an (n−1)-th row to be input with a scan signal SCAN(n−1), that is, a first reset control signal RESET1(n) is the same as the scan signal SCAN(n−1). In this way, signal lines of the display panel may be reduced, and a narrow bezel of the display panel may be achieved.

In some examples, as shown in FIG. 2, the drive transistor T3 is electrically connected with the light emitting element EL, and outputs a drive current to drive the light emitting element EL to emit light under control of the scan signal SCAN, the data signal DATA, the first voltage signal VDD, the second voltage signal VSS, and the like. A gate of a data writing transistor T4 is electrically connected with a scan line GL, a first electrode of the data writing transistor T4 is electrically connected with a data line DL, and a second electrode of the data writing transistor T4 is electrically connected with a first electrode of the drive transistor T3. A gate of a threshold compensation transistor T2 is electrically connected with a scan line GL, a first electrode of the threshold compensation transistor T2 is electrically connected with a gate of the drive transistor T3, and a second electrode of the threshold compensation transistor T2 is electrically connected with a second electrode of the drive transistor T3. A gate of a first light emitting control transistor T5 is electrically connected with a light emitting control line EML, a first electrode of the first light emitting control transistor T5 is electrically connected with a first power supply line PL1, and a second electrode of the first light emitting control transistor T5 is electrically connected with the first electrode of the drive transistor T3. A gate of a second light emitting control transistor T6 is electrically connected with the light emitting control line EML, a first electrode of the second light emitting control transistor T6 is electrically connected with the second electrode of the drive transistor T3, and a second electrode of the second light emitting control transistor T6 is electrically connected with an anode of the light emitting element EL. The first reset transistor T1 is electrically connected with the gate of the drive transistor T3 and configured to reset the gate of the drive transistor T3, and the second reset transistor T7 is electrically connected with the anode of the light emitting element EL and configured to reset the anode of the light emitting element EL. A gate of the first reset transistor T1 is electrically connected with a first reset control line RST1, a first electrode of the first reset transistor T1 is electrically connected with an initial signal line INIT, and a second electrode of the first reset transistor T1 is electrically connected with the gate of the drive transistor T3. A gate of the second reset transistor T7 is electrically connected with a second reset control line RST2, a first electrode of the second reset transistor T7 is electrically connected with the initial signal line INIT, and a second electrode of the second reset transistor T7 is electrically connected with the anode of the light emitting element EL. A first capacitance electrode plate of a storage capacitor Cst is electrically connected with the gate of the drive transistor T3, and a second capacitance electrode plate of the storage capacitor Cst is electrically connected with the first power supply line PL1.

In the present example, a first node N1 is a connection point of the storage capacitor Cst, the first reset transistor T1, the drive transistor T3, and the threshold compensation transistor T2; a second node N2 is a connection point of the first light emitting control transistor T5, the data writing transistor T4, and the drive transistor T3; a third node N3 is a connection point of the drive transistor T3, the threshold compensation transistor T2, and the second light emitting control transistor T6; and a fourth node N4 is a connection point of the second light emitting control transistor T6, the second reset transistor T7, and the light emitting element EL.

A working process of the pixel circuit shown in FIG. 2 will be described below with reference to FIG. 3. The description is given by taking a case in which a plurality of transistors included in the pixel circuit shown in FIG. 2 are all P-type transistors as an example. In the present example, a second reset control line RST2 may be connected with a scan line GL to be input with a scan signal SCAN.

In some examples, as shown in FIG. 2 and FIG. 3, during one frame of display period, a working process of the pixel circuit may include a first stage S1, a second stage S2, and a third stage S3.

The first stage S1 is referred to as a reset stage. A first reset control signal RESET1 provided by the first reset control line RST1 is a low-level signal, so that the first reset transistor T1 is turned on, and an initial signal provided by the initial signal line INIT is provided to the first node N1 to initialize the first node N1 and clear an original data voltage in the storage capacitor Cst. A scan signal SCAN provided by the scan line GL is a high-level signal, and a light emitting control signal EM provided by the light emitting control line EML is a high-level signal, so that the data writing transistor T4, the threshold compensation transistor T2, the first light emitting control transistor T5, the second light emitting control transistor T6, and the second reset transistor T7 are turned off. In this stage, the light emitting element EL does not emit light.

A second stage S2 is referred to as a data writing stage or a threshold compensation stage. A scan signal SCAN provided by the scan line GL is a low-level signal, a first reset control signal RESET1 provided by the first reset control line RST1 and an emitting control signal EM provided by the emitting control line EML are both high-level signals, and the data line DL outputs a data signal DATA. In this stage, the second electrode of the storage capacitor Cst is at a low level, so that the drive transistor T3 is turned on. The scan signal SCAN is a low-level signal, so that the threshold compensation transistor T2, the data writing transistor T4, and the second reset transistor T7 are turned on. The threshold compensation transistor T2 and the data writing transistor T4 are turned on, so that a data voltage Vdata output by the data line DL is provided to the first node N1 through the second node N2, the turned-on drive transistor T3, the third node N3, and the turned-on threshold compensation transistor T2, and the storage capacitor Cst is charged with a difference between the data voltage Vdata output by the data line DL and a threshold voltage of the drive transistor T3. A voltage of a first capacitance electrode plate (that is, the first node N1) of the storage capacitor Cst is Vdata−|Vth|, where Vdata is the data voltage output by the data line DL, and Vth is the threshold voltage of the drive transistor T3. The second reset transistor T7 is turned on, so that an initial signal Vinit provided by the initial signal line INIT is provided to the anode of the light emitting element EL to initialize (reset) the anode of the light emitting element EL and clear a pre-stored voltage therein, so as to complete initialization, thereby ensuring that the light emitting element EL does not emit light. The first reset control signal RESET1 provided by the first reset control line RST1 is a high-level signal, so that the first reset transistor T1 is turned off. The light emitting control signal EM provided by the light emitting control signal line EML is a high-level signal, so that the first light emitting control transistor T5 and the second light emitting control transistor T6 are turned off.

The third stage S3 is referred to as a light emitting stage. A light emitting control signal EM provided by the light emitting control signal line EML is a low-level signal, and a scan signal SCAN provided by the scan line GL and a first reset control signal RESET1 provided by the first reset control line RST1 are high-level signals. The light emitting control signal EM provided by the light emitting control signal line EML is a low-level signal, so that the first light emitting control transistor T5 and the second light emitting control transistor T6 are turned on, and a first voltage signal VDD output by the first power supply line PL1 provides a drive voltage to the anode of the light emitting element EL through the turned-on first light emitting control transistor T5, the drive transistor T3, and the second light emitting control transistor T6, so as to drive the light emitting element EL to emit light.

In a drive process of the pixel circuit, a drive current flowing through the drive transistor T3 is determined by a voltage difference between the gate and the first electrode of the drive transistor M3. Since the voltage of the first node N1 is Vdata−|Vth|, the drive current of the drive transistor T3 is as follows.

I=K×(Vgs−Vth)²=K×[(VDD−Vdata+|Vth|)−Vth]²=K×[(VDD−Vdata)]²

Herein, I is the drive current flowing through the drive transistor T3, that is, the drive current for driving the light emitting element EL; K is a constant; Vgs is the voltage difference between the gate and the first electrode of the drive transistor T3; Vth is the threshold voltage of the drive transistor T3; Vdata is the data voltage output by the data line DL; and VDD is the first voltage signal output by the first power supply line PL1.

It may be seen from the above formula that a current flowing through the light emitting element EL has nothing to do with the threshold voltage of the drive transistor T3. Therefore, the pixel circuit of the present embodiment may better compensate the threshold voltage of the drive transistor T3.

FIG. 4 is a partial schematic diagram of a display panel according to at least one embodiment of the present disclosure. In some examples, as shown in FIG. 4, the first display area A1 of the display panel may include a plurality of first light emitting elements 21 arranged in an array. The second display area A2 may include a plurality of first pixel circuits 11 and a plurality of second pixel circuits 12 arranged in an array, and a plurality of second light emitting elements (not shown) arranged in an array. In the present example, the second display area A2 may surround the first display area A1. In the second display area A2, the plurality of first pixel circuits 11 may be located on a side of the plurality of second pixel circuits 12 away from the first display area A1 along a first direction X. For example, the plurality of first pixel circuits 11 may be located at an edge of the second display area A2 close to the peripheral region along the first direction X. The plurality of first pixel circuits 11 may be arranged close to a left bezel region and the right bezel region.

In some examples, as shown in FIG. 4, the plurality of pixel circuits arranged along the first direction X may be referred to as a row of pixel circuits, and the plurality of pixel circuits arranged along a second direction Y may be referred to as a column of pixel circuits. In the second display area A2, at least one column of first pixel circuits 11 may be provided at an edge of a plurality of columns of second pixel circuits 12. For example, a plurality of columns (e.g., three columns, four columns, or five columns) of first pixel circuits 11 may be respectively provided on opposite sides of the plurality of columns of second pixel circuits 12 along the first direction X. Quantities of the columns of the first pixel circuits 11 provided on opposite sides of the plurality of columns of second pixel circuits 12 along the first direction X may be the same (for example, three columns of the first pixel circuits are provided on opposite sides). In the present example, by providing the first pixel circuits at an edge of the second pixel circuits, there is no need to compress the second pixel circuits to arrange the first pixel circuits, which may avoid providing too many redundant pixel circuits, maintain the arrangement mode and size of the second pixel circuits, and improve the reliability of the second pixel circuits, thereby improving the display effect of the display panel.

In some examples, at least one first pixel circuit 11 in the second display area A2 may be electrically connected with at least one first light emitting element 21 in the first display area A1 by means of at least one connecting line, and configured to drive the first light emitting element 21 to emit light. An orthographic projection of the first light emitting element 21 on the base substrate may not be overlapped with an orthographic projection of the first pixel circuit 11 electrically connected thereto on the base substrate. For example, one end of the connecting line may be electrically connected with the first pixel circuit 11, and the other end may extend from the second display area A2 to the first display area A1, and be electrically connected with the first light emitting element 21 in the first display area A1. At least one second pixel circuit 12 in the second display area A2 may be electrically connected with at least one second light emitting element 12, and configured to drive the at least one second light emitting element 12 to emit light. An orthographic projection of the second light emitting element on the base substrate may be overlapped with an orthographic projection of the second pixel circuit 12 electrically connected thereto on the base substrate.

In some examples, as shown in FIG. 4, the first display area A1 may have a first midline OO′ along the first direction X, the first light emitting elements 21 in a half region of the first display area A1 to the left of the first midline OO′ may be electrically connected with a plurality of columns (e.g., three columns) of the first pixel circuits 11 close to a left edge of the second display area by means of connecting lines, and the first light emitting elements 21 in a half region of the first display area A1 to the right of the first midline OO′ may be electrically connected with a plurality of columns (e.g., three columns) of the first pixel circuits 11 close to a right edge of the second display area by means of connecting lines. In the present example, one first pixel circuit may be configured to drive one first light emitting element to emit light, or may be configured to drive two or more first light emitting elements emitting light of a same color to emit light. However, the present embodiment is not limited thereto.

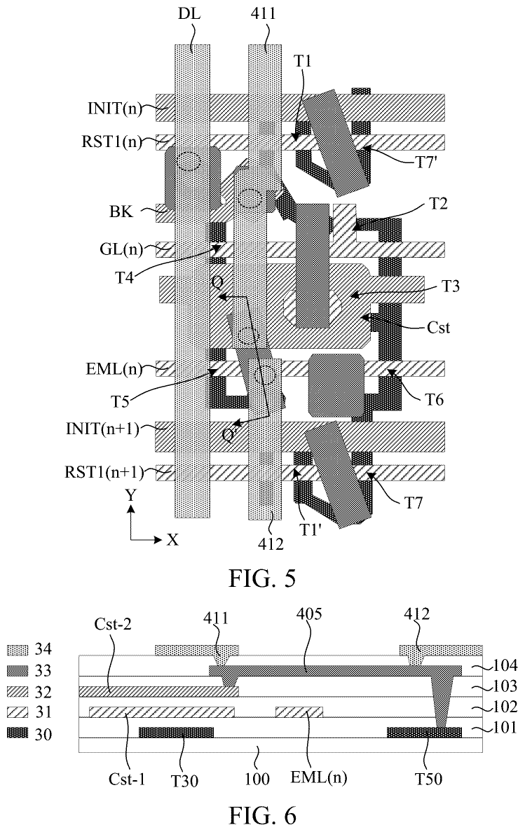

FIG. 5 is a plan schematic diagram of a first pixel circuit according to at least one embodiment of the present disclosure. FIG. 6 is a schematic partial cross-sectional view along a Q-Q′ direction in FIG. 5.

In some examples, as shown in FIG. 5, in a plane parallel to the display panel, the display panel may include a scan line GL(n), a light emitting control line EML(n), first reset control lines RST1(n) and RST1(n+1), initial signal lines INIT(n) and INIT(n+1), a data line DL, a plurality of power supply connection segments (e.g., power supply connection terminals 411 and 412), and a first pixel circuit. The first pixel circuit may include a plurality of transistors and a storage capacitor Cst. The plurality of transistors may include a drive transistor T3, a data writing transistor T4, a threshold compensation transistor T2, a first reset transistor T1, a second reset transistor T7, a first light emitting control transistor T5, and a second light emitting control transistor T6.

FIG. 5 illustrates a plurality of transistors T1 to T7 of a first pixel circuit in an n-th row, a second reset transistor T7′ of a first pixel circuit in an (n−1)-th row, and a first reset transistor T1′ of a first pixel circuit in an (n+1)-th row. As shown in FIG. 5, the first reset transistor T1 of the first pixel circuit in the n-th row is electrically connected with a first reset control line RST1(n), the first reset control line RST1(n) is connected with a scan line GL(n−1) electrically connected with the first pixel circuit in the (n−1)-th row, and the second reset transistor T7′ of the first pixel circuit in the (n−1)-th row is electrically connected with the first reset control line RST1(n), to achieve input of a scan signal SCAN(n−1). The first reset transistor T1′ of the first pixel circuit in the (n+1)-th row is electrically connected with a first reset control line RST1(n+1), the first reset control line RST1(n+1) is electrically connected with a scan line GL(n) connected with the first pixel circuit in the n-th row, and the second reset transistor T7 of the first pixel circuit in the n-th row is electrically connected with the first reset control line RST1(n+1), to achieve input of a scan signal SCAN(n).

In some examples, as shown in FIG. 6, in a direction perpendicular to the display panel, the circuit structure layer of the display panel may include a semiconductor layer 30, a first conductive layer 31, a second conductive layer 32, a third conductive layer 33, and a fourth conductive layer 34 which are sequentially provided on the base substrate 100. A first insulation layer 101 may be provided between the semiconductor layer 30 and the first conductive layer 31, a second insulation layer 102 may be provided between the first conductive layer 31 and the second conductive layer 32, a third insulation layer 103 may be provided between the second conductive layer 32 and the third conductive layer 33, and a fourth insulation layer 104 may be provided between the third conductive layer 33 and the fourth conductive layer 34. A fifth insulation layer may be provided on a side of the fourth conductive layer 34 away from the base substrate 100. In some embodiments, the first insulation layer 101 to the third insulation layer 103 may be inorganic material layers, and the fourth insulation layer 104 and the fifth insulation layer may be organic material layers. However, the present embodiment is not limited thereto.

A structure of the display panel will now be described through an example of a preparation process of the display panel. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on an underlay substrate by using deposition, coating, or another process. If the “thin film” does not need to be processed through a patterning process in the entire preparing process, the “thin film” may also be called a “layer”. If the “thin film” needs to be processed through the patterning process in the entire p process, the “thin film” is called a “thin film” before the patterning process is performed and is called a “layer” after the patterning process is performed. At least one “pattern” is contained in the “layer” which has been processed through the patterning process.

“A and B have a same layer structure” or “A and B are disposed in a same layer” mentioned in the embodiments of the present disclosure means that A and B are formed simultaneously through a same patterning process, or surfaces of A and B close to a base substrate have basically a same distance from the base substrate, or surfaces of A and B close to the base substrate are in direct contact with a same film layer. A “thickness” of a film layer is a dimension of the film layer in a direction perpendicular to the display panel. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some examples, a preparation process of a display panel may include following operations.

(1) A base substrate is provided. In some examples, the base substrate may be a flexible base substrate or may be a rigid base substrate. For example, the rigid base substrate may be made of a material such as glass or quartz. The flexible base substrate may be made of a material such as Polyimide (PI), and the flexible base substrate may be of a single-layer structure or a laminated structure composed of an inorganic material layer and a flexible material layer. However, the present embodiment is not limited thereto.

(2) A semiconductor layer is formed. In some examples, a semiconductor thin film is deposited on the base substrate in the second display area, and the semiconductor thin film is patterned by a patterning process to form a semiconductor layer in the second display area.

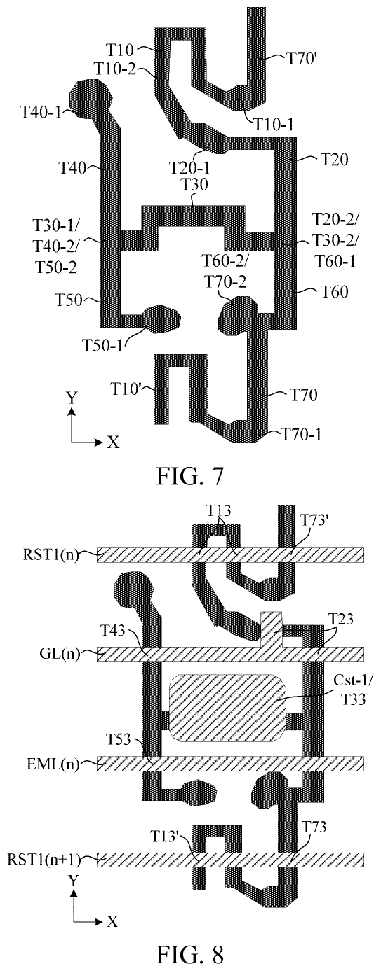

FIG. 7 is a partial schematic diagram of a second display area after a semiconductor layer is formed in FIG. 5. In some examples, as shown in FIG. 7, the semiconductor layer of the second display area may at least include active layers of a plurality of transistors of a first pixel circuit, for example, including a first active layer T10 of a first reset transistor, a second active layer T20 of a threshold compensation transistor, a third active layer T30 of a drive transistor, a fourth active layer T40 of a data writing transistor, a fifth active layer T50 of a first light emitting control transistor, a sixth active layer T60 of a second light emitting control transistor, and a seventh active layer T70 of a second reset transistor of the first pixel circuit. The first active layer T10 to the seventh active layer T70 may be of an interconnected integral structure. The first active layer T10 and the seventh active layer T70′ of the first pixel circuit in a previous row may be of an integral structure, and the seventh active layer T10 and the first active layer T10′ of the first pixel circuit in the next row may be of an integral structure.

In some exemplary embodiments, as shown in FIG. 7, the first active layers T10 and T10′ may have a substantially “n” shape, the second active layer T20 may have a substantially “ [symbol] ”, the third active layer T30 may have a substantially “ [symbol] ” shape, the fourth active layer T40 may have a substantially “I” shape, and the fifth active layer T50, the sixth active layer T60, and the seventh active layers T70 and T70′ may have a substantially “L” shape.

In some examples, an active layer of each transistor may include a first region, a second region, and a channel region located between the first region and the second region. In some examples, as shown in FIG. 7, a first region T10-1 of the first active layer T10 simultaneously serves as a first region of a seventh active layer T70′ of a seventh transistor T7′ of a first pixel circuit of a previous row, a second region T10-2 of the first active layer T10 simultaneously serves as a first region T20-1 of the second active layer T20, a first region T30-1 of the third active layer T30 simultaneously serves as a second region T40-2 of the fourth active layer T40 and a second region T50-2 of the fifth active layer T50, a second region T30-2 of the third active layer T30 simultaneously serves as a second region T20-2 of the second active layer T20 and a first region T60-1 of the sixth active layer T60, and a second region T60-2 of the sixth active layer T60 simultaneously serves as a second region T70-2 of the seventh active layer T70.

(3) A first conductive layer is formed. In some examples, a first insulation thin film and a first conductive thin film are sequentially deposited on the base substrate where the aforementioned structures are formed, and the first conductive thin film is patterned by a patterning process to form a first insulation layer covering the semiconductor layer, and a first conductive layer provided on the first insulation layer of the second display area.

FIG. 8 is a partial schematic diagram of a second display area after a first conductive layer is formed in FIG. 5. In some examples, as shown in FIG. 8, the first conductive layer of the second display area may at least include a first capacitance electrode plate Cst-1 of the storage capacitance of the first pixel circuit, gates of a plurality of transistors of the first pixel circuit (for example, including a gate T13 of the first reset transistor of the first pixel circuit, a gate T23 of the threshold compensation transistor, a gate T33 of the drive transistor, a gate T43 of the data writing transistor, a gate T53 of the first light emitting control transistor, a gate T63 of the second light emitting control transistor, and a gate T73 of the second reset transistor), and a scan line GL(n), a light emitting control line EML(n), and first reset control lines RST1(n) and RST1(n+1) which extend along the first direction X. The first capacitance electrode plate Cst-1 of the storage capacitor Cst may be in a shape of a rectangle, and corners of the rectangle may be chamfered. There is an overlapping region between an orthographic projection of the first capacitance electrode plate Cst-1 on the base substrate and an orthographic projection of the third active layer T30 of the drive transistor T3 on the base substrate. The first capacitance electrode plate Cst-1 of the storage capacitor Cst simultaneously serves as the gate T33 of the drive transistor T3. The scan line GL, the gate T43 of the data writing transistor T4, and the gate T23 of the threshold compensation transistor T2 may be of an integral structure. The light emitting control line EML(n), the gate T53 of the first light emitting control transistor T5, and the gate T63 of the second light emitting control transistor T6 may be of an integral structure. The first reset control line RST1(n), the gate T13 of the first reset transistor T1, and the gate T73′ of the second reset transistor T7′ of a pixel circuit in a previous row may be of an integral structure. The first reset control line RST1(n+1), the gate T73 of the second reset transistor T7, and the gate T13′ of the first reset transistor T1′ of a pixel circuit in a next row may be of an integral structure.

(4) A second conductive layer is formed. In some examples, a second insulation thin film and a second conductive thin film are sequentially deposited on the base substrate where the aforementioned structures are formed, and the second conductive thin film is patterned by a patterning process to form a second insulation layer covering the first semiconductor layer and a second conductive layer provided on the second insulation layer of the second display area.

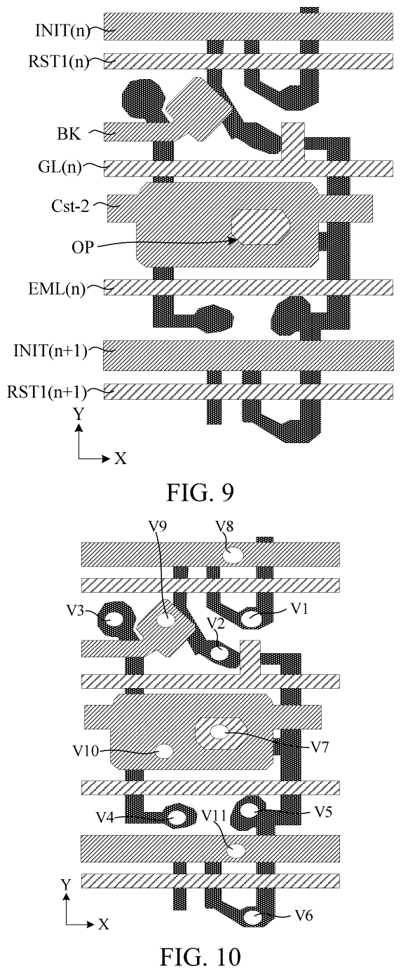

FIG. 9 is a partial schematic diagram of a second display area after a second conductive layer is formed in FIG. 5. In some examples, as shown in FIG. 9, the second conductive layer of the second display area may at least include a second capacitance electrode plate Cst-2 of the storage capacitor Cst of the first pixel circuit, a shield electrode BK, and initial signal lines INIT(n) and INIT(n+1) extending along the first direction X. An orthographic projection of the second capacitance electrode plate Cst-2 of the storage capacitor Cst on the base substrate may be located between an orthographic projection of the scan line GL(n) on the base substrate and an orthographic projection of the light emitting control line EML(n) on the base substrate. There is an overlapping region between the orthographic projection of the second capacitance electrode plate Cst-2 of the storage capacitor Cst on the base substrate and an orthographic projection of the first capacitance electrode plate Cst-1 of the storage capacitor Cst on the base substrate. The second capacitance electrode plate Cst-2 of the storage capacitor Cst may be provided with a hollow region OP. The hollow region OP may include a second insulation layer covering the first capacitance electrode plate Cst-1, and the orthographic projection of the first capacitance electrode plate Cst-1 on the base substrate may include an orthographic projection of the hollow region OP on the base substrate. The shield electrode BK is located on a side of the scan line GL(n) away from the storage capacitor Cst. The shield electrode BK is configured to shield an influence of a data voltage jump on a key node, and avoid an influence of the data voltage jump on a potential of the key node of the first pixel circuit, thereby improving the display effect.

(5) A third insulation layer is formed. In some examples, a third insulation thin film is deposited on the base substrate where the aforementioned structures are formed, and a third insulation layer is formed by a patterning process. The third insulation layer is formed with a plurality of vias.

FIG. 10 is a partial schematic diagram of a second display area after a third insulation layer is formed in FIG. 5. In some examples, as shown in FIG. 10, the third insulation layer of the second display area may be provided with a plurality of vias, which may include, for example, a first via V1 to an eleventh via V11. The third insulation layer, the second insulation layer, and the first insulation layer in the first via V1 to the sixth via V6 are removed to expose a surface of the semiconductor layer. The third insulation layer and the second insulation layer in the seventh via V7 may be removed to expose a surface of the first conductive layer. The third insulation layer in the eighth via V8 to the eleventh via V11 may be removed to expose a surface of the second conductive layer.

(6) A third conductive layer is formed. In some examples, a third conductive thin film is deposited on the base substrate where the aforementioned structures are formed, and the third conductive thin film is patterned by a patterning process to form a third conductive layer located on the third insulation layer.

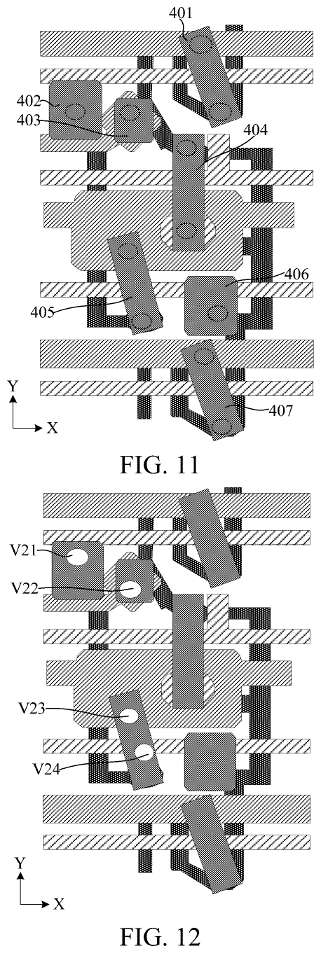

FIG. 11 is a partial schematic diagram of a second display area after the third conductive layer is formed in FIG. 5. In some examples, as shown in FIG. 11, the third conductive layer of the second display area may at least include a plurality of lap islands (for example, a first lap island 401 to a seventh lap island 407), and a plurality of connecting lines (not shown).

In some examples, the first lap island 401 may be electrically connected with the first region T10-1 of the first active layer of the first reset transistor of the first pixel circuit through the first via V1, and may also be electrically connected with the initial signal line INIT(n) through the eighth via V8. The second lap island 402 may be electrically connected with the first region T40-1 of the fourth active layer of the data writing transistor of the first pixel circuit through the third via V3. The third lap island 403 may be electrically connected with the shield electrode BK through the ninth via V9. The fourth lap island 404 may be electrically connected with the first region T20-1 of the second active layer of the threshold compensation transistor through the second via V2, and may also be electrically connected with the first capacitance electrode plate Cst-1 of the storage capacitor Cst through the seventh via V7. The fifth lap island 405 may be electrically connected with the first region T50-1 of the fifth active layer of the first light emitting control transistor through the fourth via V4, and may also be electrically connected with the second capacitance electrode plate Cst-2 of the storage capacitor Cst through the tenth via V10. The sixth lap island 406 may be electrically connected with the second region T60-2 of the sixth active layer of the second light emitting control transistor through the fifth via V5. The seventh lap island 407 may be electrically connected with the first region T70-1 of the seventh active layer of the second reset transistor of the first pixel circuit through the sixth via V6, and may also be electrically connected with the initial signal line INIT(n+1) through the eleventh via V11.

In some examples, the connecting line to which the first pixel circuit is connected may be integrated with the sixth lap island 406, and the connecting line may extend from the second display area to the first display area and be electrically connected with an anode of the first light emitting element located in the first display area, thereby realizing electrical connection between the first pixel circuit and the first light emitting element.

In some examples, the third conductive layer may be made of a transparent conductive material, such as Indium Tin Oxide (ITO). In the present example, by providing the third conductive layer as a transparent conductive material, and locating the connecting lines on the third conductive layer, the influence of the arrangement of the connecting lines on the light transmittance of the first display area may be reduced, thereby ensuring the display effect and light transmittance of the first display area. In the present example, the third conductive layer is only provided with a lap island for lapping, but not provided with a penetrating wiring along the second direction Y, so that the connecting lines located in the third conductive layer may extend along the first direction X to realize electrical connection between the first pixel circuit and the first light emitting element.

(7) A fourth insulation layer is formed. In some examples, a fourth insulation thin film is coated on the base substrate where the aforementioned structures are formed, and a fourth insulation layer is formed by a patterning process. The fourth insulation layer may be provided with a plurality of vias.

FIG. 12 is a partial schematic diagram of a second display area after a fourth insulation layer is formed in FIG. 5. In some examples, as shown in FIG. 12, the fourth insulation layer of the second display area may be provided with a plurality of vias, which may include, for example, a twenty-first via V21 to a twenty-fourth via V24. The fourth insulation layer in the twenty-first via V21 to the twenty-fourth via V24 may be removed to expose a surface of the third conductive layer.

(8) A fourth conductive layer is formed. In some examples, a fourth conductive thin film is deposited on the base substrate where the aforementioned structures are formed, and the fourth conductive thin film is patterned by a patterning process to form a fourth conductive layer provided on the fourth insulation layer of the second display area.

In some examples, as shown in FIG. 5, the fourth conductive layer of the second display area may at least include a data line DL, and a plurality of power supply connection segments (for example, power supply connection segments 411 and 412). The data line DL may extend along the second direction Y and be electrically connected with the second lap island 402 through the twenty-first via V21, thereby realizing electrical connection with the first electrode of the data writing transistor of the first pixel circuit. A plurality of power supply connection segments may extend along the second direction Y. The power supply connection segment 411 may be electrically connected with the third lap island 403 through the twenty-second via V22, and may also be electrically connected with the fifth lap island 405 through the twenty-third via V23. The power supply connection segment 412 may be electrically connected with the fifth lap island 405 through the twenty-fourth via V24. The power supply connection segments 411 and 412 may be electrically connected by the fifth lap island 405. The power supply connection segments 411 and 412 may be provided at intervals along the second direction Y. In the area where the pixel circuit is located, adjacent power supply connection segments 411 and 412 may realize electrical connection with the storage capacitor and the first light emitting control transistor through the fifth lap island 405. In an interval region between the pixel circuits, adjacent power supply connection segments 411 and 412 may be of an integral structure. In the present example, the electrical connection between the power supply connection segment and the pixel circuit is realized through the fifth lap island, which may prevent the power supply connection segment located on the fourth conductive layer from realizing the electrical connection with the pixel circuit directly through the via exposing the semiconductor layer, avoid the defects caused by the vias with an excessive depth in the preparation process, and ensure the transmission effect of a first voltage signal. However, the present embodiment is not limited thereto. In some other examples, the power supply connection segments located on the fourth conductive layer may be of an integral structure, so as to realize transmission of the first voltage signal. In some other examples, the third lap island may be omitted, and the power supply connection segment may be electrically connected directly to the shield electrode located in the second conductive layer.

In some examples, a structure of the second pixel circuit is substantially the same as a structure of the first pixel circuit in the second display area, so this will not be described here. The second light emitting control transistor of the second pixel circuit may be electrically connected with the anode of the second light emitting element through a sixth lap island located in the third conductive layer. Alternatively, the fourth conductive layer may further include an anode connection electrode, and the second light emitting control transistor of the second pixel circuit may be electrically connected with the anode of the second light emitting element through a sixth lap island located on the third conductive layer and the anode connection electrode located on the fourth conductive layer. The present embodiment is not limited thereto.

In some examples, after forming the aforementioned structures, the first display area may include a first insulation layer, a second insulation layer, a third insulation layer, and a fourth insulation layer which are stacked on the base substrate. Subsequently, an anode thin film may be deposited on the base substrate where the aforementioned patterns are formed, and the anode thin film is patterned by a patterning process to form an anode layer. The anode layer may include an anode of a first light emitting element located in the first display area and an anode of a second light emitting element located in the second display area. Then, a pixel definition thin film is coated and a pixel definition layer is formed by masking, exposure and development processes. The pixel definition layer may be formed with a plurality of pixel openings exposing the anode layer. An organic light emitting layer is formed in the pixel openings formed earlier, and the organic light emitting layer is connected with the anode layer. Subsequently, a cathode thin film is deposited, and the cathode thin film is patterned by a patterning process to form a pattern of a cathode. The cathode is connected with the organic light emitting layer. Then, an encapsulation structure layer is formed on the cathode. For example, the encapsulation structure layer may include a stacked structure of an inorganic material/an organic material/an inorganic material.

In some examples, the first insulation layer, the second insulation layer, and the third insulation layer may be made of any one or more of Silicon Oxide (SiOx), Silicon Nitride (SiNx), and Silicon Oxynitride (SiON), and may be a single layer, a multi-layer, or a composite layer. The first insulation layer and the second insulation layer may be referred to as Gate Insulation (GI) layers, and the third insulation layer may be referred to as an Interlayer Dielectric (ILD) layer. The fourth insulation layer may be made of an organic material, such as polyimide, acrylic, or polyethylene terephthalate. The first conductive layer, the second conductive layer, and the fourth conductive layer may be made of a metallic material, such as any one or more of Argentum (Ag), Copper (Cu), Aluminum (Al), and Molybdenum (Mo), or an alloy material of the abovementioned metals, such as an Aluminum-Neodymium alloy (AlNd) or a Molybdenum-Niobium alloy (MoNb), and may be of a single-layer structure, or a multilayer composite structure, such as Mo/Cu/MO, or Ti/Al/Ti. For example, a material of the first conductive layer and the second conductive layer may be molybdenum, and a material of the fourth conductive layer may be a laminated structure of titanium-aluminum-titanium. The semiconductor layer may be made of various materials, such as amorphous Indium Gallium Zinc Oxide (a-IGZO), Zinc Oxynitride (ZnON), Indium Zinc Tin Oxide (IZTO), amorphous Silicon (a-Si), poly Silicon (p-Si). That is, the present disclosure is applicable to transistors prepared based on an oxide technology, a silicon technology, and an organic matter technology. The pixel definition layer may be made of an organic material, such as polyimide, acrylic, or polyethylene terephthalate. The anode layer may be made of a reflective material such as a metal, and the cathode layer may be made of a transparent conductive material. However, the present embodiment is not limited thereto.

The structure and the preparation process of the display panel of the present embodiment are merely illustrative. In some exemplary implementations, a corresponding structure may be changed and a patterning process may be added or removed according to actual needs. For example, the connecting line between the first pixel circuit and the first light emitting element may be located between the third conductive layer and the fourth conductive layer, or may be located between the third conductive layer and the second conductive layer. In this case, the plurality of connecting lines may be made of a transparent conductive material, and the third conductive layer may be made of a metal material.

The preparation process of the present exemplary embodiment may be implemented using an existing mature preparation device, and may be compatible well with an existing preparation process, simple in process implementation, easy to implement, high in a production efficiency, low in a production cost, and high in yield.

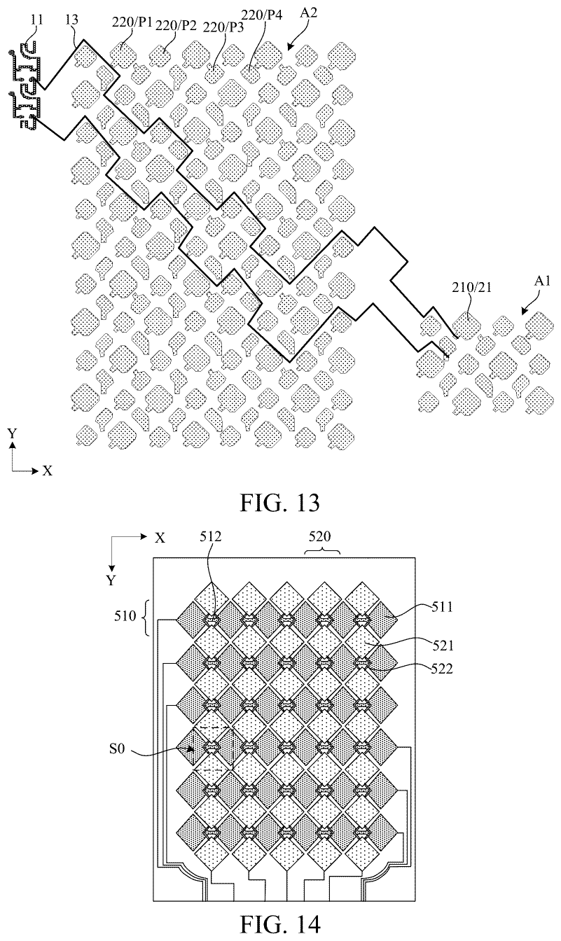

FIG. 13 is a schematic diagram showing extension of a connecting line according to at least one embodiment of the present disclosure. In FIG. 13, two connecting lines 13 are used as an example to illustrate a manner in which the connecting lines extend in the second display area A2 and the first display area A1. In some examples, as shown in FIG. 13, arrangement of the first light emitting elements in the first display area A1 may be substantially the same as arrangement of the second light emitting elements in the second display area A2. For example, one pixel circuit of the display area may include four sub-pixels, such as a first sub-pixel P1 emitting light of a first color, a second sub-pixel P2 emitting light of a second color, and a third sub-pixel P3 and a fourth sub-pixel P4 emitting light of a third color In some examples, the light of the first color may be blue light, the light of the second color may be red light, and the light of the third color may be green light. Along the first direction X, the first sub-pixels P1 and the second sub-pixels P2 are arranged in a row at intervals, the third sub-pixels P3 and the fourth sub-pixels P4 are arranged in a row at intervals, and the rows in which the first sub-pixels P1 and the second sub-pixels P2 are located are misaligned with the rows in which the third sub-pixels P3 and the fourth sub-pixels P4 are located. Along the second direction Y, the first sub-pixels P1 and the second sub-pixels P2 may be arranged in a column at intervals, the third sub-pixels P3 and the fourth sub-pixels P4 may be arranged in a column at intervals, and the columns in which the first sub-pixels P1 and the second sub-pixels P2 are located are misaligned with the columns in which the third sub-pixels P3 and the fourth sub-pixels P4 are located.

In some examples, as shown in FIG. 13, one end of the connecting line 13 may be electrically connected with the first pixel circuit 11, and the other end may extend from the second display area A2 to the first display area A1 and be electrically connected with the anode 210 of the corresponding first light emitting element 21. In the second display area A2, an orthographic projection of the connecting line 13 on the base substrate may is not overlapped with an orthographic projection of the anode 220 of the second light emitting element on the base substrate. In other words, the connecting lines 13 may be arranged in an interval region between the anodes 220 of the second light emitting elements. An orthographic projection of the anode of the second light emitting element on the base substrate may be overlapped with an orthographic projection of the second pixel circuit connected thereto on the base substrate. For example, the orthographic projection of the anode of the second light emitting element on the base substrate may cover an orthographic projection of all or most of the vias provided by the second pixel circuit on the third insulation layer on the base substrate. In this way, the connecting lines 13 bypass the anode 220 of the second light emitting element so as to avoid the vias provided on the third insulation layer as much as possible, thereby avoiding molar lines that may be caused by the linearly arranged connecting lines.

In some examples, as shown in FIG. 13, an orthographic projection of the plurality of connecting lines 13 on the base substrate may form a mesh shape. For example, two adjacent connecting lines 13 extending in the same direction (e.g., in a direction intersecting with both the first direction X and the second direction Y) may be wound sequentially around the anodes 220 of six second light emitting elements and around anodes 220 of two second light emitting elements in order, so as to bypass the anodes of the second light emitting elements 220. The winding mode of the plurality of connecting lines 13 in the first display area A1 may be similar to that in the second display area A2. In the first display area A1, the plurality of connecting lines 13 may bypass the anode of the first light emitting element which is not connected thereto, and finally electrically connect to the anode 210 of the first light emitting element which is connected thereto.

In the present example, by designing the wiring mode of the connecting lines and providing the connecting lines on the third conductive layer, the preparation process of the display panel may be reduced, and there is no need to prepare a plurality of transparent conductive layers on a side of the fourth conductive layer away from the base substrate to arrange the connecting lines. Moreover, the wiring mode of the connecting lines in the present example may also meet the display effect of the display panel, thereby realizing full-screen display. The display panel of the present example has better design adaptability and good compatibility. Moreover, the preparation process of the present example is close to a production process of an actual production line, which is conducive to introducing into actual production and may reduce the production cost of the full screen.

In some examples, the display panel may further include a touch structure layer provided on a side of the encapsulation structure layer away from the base substrate. For example, a structure in which a touch structure layer is on a thin film encapsulation (Touch on Thin Film Encapsulation, referred to as Touch on TFE) is formed. The display structure and the touch structure are integrated together, which has advantages of being light, thin, and foldable, and may meet requirements of products, such as flexible folding, and the like. Structures of Touch on TFE mainly include a Flexible Multi-Layer On Cell (FMLOC for short) structure and a Flexible Single-Layer On Cell (FSLOC for short) structure. The FMLOC structure is based on a working principle of mutual capacitance detection. Generally, a drive (Tx) electrode and a sensing (Rx) electrode are formed by two layers of metal, and an Integrated Circuit (IC for short) achieves a touch action by detecting a mutual capacitance between the drive electrode and the sensing electrode. The FSLOC structure is based on an operating principle of self-capacitance (or voltage) detection. Generally, a touch electrode is formed by a single layer of metal, and an integrated circuit achieves a touch action by detecting the self-capacitance (or voltage) of the touch electrode.

FIG. 14 is a schematic diagram of architecture of a touch structure layer according to at least one embodiment of the present disclosure. In this example, two layers of metal are overlapped to form a mutual capacitance as an example. In some examples, as shown in FIG. 14, the display area may include a plurality of first touch units 510 and a plurality of second touch units 520. First touch units 510 may extend along a first direction X, and the plurality of first touch units 510 may be sequentially arranged along a second direction Y. Second touch units 520 may extend along the second direction Y, and the plurality of second touch units 520 may be sequentially arranged along the first direction X. Each first touch unit 510 may include a plurality of first touch electrodes 511 and a plurality of first connecting portions 512 arranged sequentially along the first direction X, and the first touch electrodes 511 and the first connecting portions 512 are alternately provided and sequentially connected. Each second touch unit 520 may include a plurality of second touch electrodes 521 arranged sequentially along the second direction Y, the plurality of second touch electrodes 521 are provided at intervals, and adjacent second touch electrodes 521 may be connected with each other through a second connecting portion 522. In some examples, a film layer where the second connecting portions 522 are located may be different from film layers where the first touch electrodes 511 and the second touch electrodes 521 are located.

In some examples, the plurality of first touch electrodes 511, the plurality of second touch electrodes 521, and the plurality of first connecting portions 512 may be provided on a same layer, i.e., a touch layer, and may be formed by a same patterning process. The first touch electrodes 511 and the first connecting portions 512 may be of an interconnected integral structure. The second connecting portions 522 may be provided on a bridging layer, and adjacent second touch electrodes 521 are electrically connected with each other through a via. A touch insulation layer may be provided between the touch layer and the bridging layer. In some other examples, the plurality of first touch electrodes 511, the plurality of second touch electrodes 521, and the plurality of second connecting portions 522 may be provided on a same layer, i.e., a touch layer. The second touch electrodes 521 and the second connecting portions 522 may be of an interconnected integral structure. The first connecting portions 512 may be provided on a bridging layer, and adjacent first touch electrodes 511 are connected with each other through a via. In some exemplary embodiments, the first touch electrodes may be sensing (Rx) electrodes, and the second touch electrodes may be drive (Tx) electrodes. Or, the first touch electrodes may be drive (Tx) electrodes, and the second touch electrodes may be sensing (Rx) electrodes. However, the present embodiment is not limited thereto.

In some examples, the first touch electrodes 511 and the second touch electrodes 521 may be in a form of a metal mesh. The metal mesh is formed by a plurality of interweaving metal wires and includes a plurality of mesh patterns. The mesh patterns are polygons formed by a plurality of metal wires. In some examples, shapes of the mesh patterns formed by the metal wires may be regular or irregular, and edges of the mesh patterns may be straight lines or curves. The present embodiment is not limited thereto. In some examples, widths of the metal wires may be less than or equal to 5 microns (μm). The first touch electrodes and the second touch electrode in the form of the metal mesh have advantages, such as a small resistance, a small thickness, and a fast response speed.

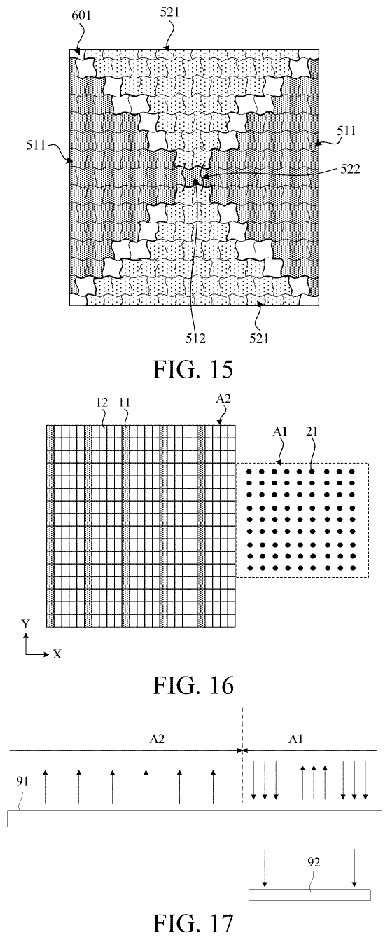

FIG. 15 is a schematic structural diagram of touch electrodes in a form of a metal mesh according to at least one embodiment of the present disclosure. FIG. 15 is a partial enlarged view of an area S0 in FIG. 14. In the present example, the mesh pattern may be rhombic, and edges of the mesh patterns may be curves. As shown in FIG. 15, in order to insulate the first touch electrodes 511 from the second touch electrodes 521 from each other, a plurality of cuts, which disconnect the metal wires of the mesh pattern, are provided in the metal mesh, to form invalid connection regions 601 between the first touch electrodes 511 and the second touch electrodes 521, thereby achieving isolation of a mesh pattern of the first touch electrodes 511 from a mesh pattern of the second touch electrodes 521. In some embodiments, a cut may be a straight line or a polyline formed by connecting a portion of straight lines, which further solves a visualization problem at a broken line of the cut.

In some exemplary embodiments, a cut may be provided in each mesh pattern located in the invalid connection regions 601. The cut cuts off metal wires of the mesh pattern so that each mesh pattern is divided into two parts, one part belonging to a first touch electrode 511 and the other part belonging to a second touch electrode 521, or one part belonging to the second touch electrode 521 and the other part belonging to the first touch electrode 511. In some examples, a first connecting portion 512 may form an integral structure with a first touch electrode 511 and be configured to implement connection between two first touch electrodes 511. For example, the first connecting portion 512 may be a mesh pattern connecting two first touch electrodes 511. A second connecting portion 522 is provided in a different layer from a second touch electrode 521, and is configured to implement connection between two second touch electrodes 521. For example, the second connecting portion 522 may include two arc-shaped connecting lines provided in parallel, one end of each arc-shaped connecting line being connected with one second touch electrode 521 and the other end being connected with the other second touch electrode 521.

In some examples, an orthographic projection of the connecting lines in the circuit structure layer on the base substrate may be covered by an orthographic projection of the metal mesh pattern of the touch electrodes on the base substrate. The connecting lines in the circuit structure layer may be arranged in a form of the metal mesh pattern of the touch electrodes. In this way, it is possible to avoid the influence of the connecting lines on the display effect and touch effect of the display panel.

FIG. 16 is another partial schematic diagram of a display panel according to at least one embodiment of the present disclosure. In some examples, as shown in FIG. 16, in the second display area A2, the plurality of first pixel circuits 11 may be distributed at intervals among the plurality of second pixel circuits 12. For example, the display panel of the present example may adopt a pixel circuit compression scheme, and by reducing sizes of the second pixel circuits along the first direction X, the first pixel circuits 11 and the second pixel circuits 12 may be arranged along the first direction X, so that the plurality of first pixel circuits 11 are dispersed in the plurality of second pixel circuits 12. For example, the first direction X may be a row direction, and among the pixel circuits in the same row, the first pixel circuits 11 may be arranged at intervals among the second pixel circuits 12. The rest of the structure of the display panel in the present embodiment may be referred to the description of the aforementioned embodiments, which will not be repeated here.

The present embodiment further provides a preparation method of a display panel, including: preparing a circuit structure layer on a base substrate, the circuit structure layer including a plurality of first pixel circuits and a plurality of second pixel circuits which are located in a second display area, and a plurality of connecting lines extending from the second display area to a first display area, the second display area being located on at least one side of the first display area; and preparing a light emitting structure layer on a side of the circuit structure layer away from the base substrate, the light emitting structure layer including a plurality of first light emitting elements located in the first display area and a plurality of second light emitting elements located in the second display area; at least one first pixel circuit being electrically connected with at least one first light emitting element by means of at least one connecting line and configured to drive the at least one first light emitting element to emit light; and at least one second pixel circuit being electrically connected with at least one second light emitting element and configured to drive the at least one second light emitting element to emit light. An orthographic projection of the plurality of connecting lines on the base substrate is not overlapped with an orthographic projection of anodes of the plurality of second light emitting elements on the base substrate.

Regarding the preparation method of the display panel in the present embodiment, reference may be made to descriptions of the aforementioned embodiments, and it will not be repeated here.

At least one embodiment of the present disclosure further provides a display apparatus including the display panel as described above.

FIG. 17 is a schematic diagram of a display apparatus according to at least one embodiment of the present disclosure. As shown in FIG. 17, the present embodiment provides a display apparatus, including a display panel 91, and a photosensitive sensor 92 located away from a light emitting side of a display structure layer of the display panel 91. An orthographic projection of the photosensitive sensor 92 on the display panel 91 is overlapped with a first display area A1.

In some examples, the display panel 91 may be a flexible OLED display panel, a QLED display panel, a Micro-LED display panel, or a Mini-LED display panel. The display apparatus may be any product or component with a display function such as an OLED display, a cell phone, a tablet, a television, a display, a laptop, a digital photo frame, and a navigator, which is not limited in the embodiments of the present disclosure.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display panel, comprising:
a base substrate, comprising a first display area and a second display area located on least one side of the first display area;
a circuit structure layer located on the base substrate, and comprising a plurality of first pixel circuits and a plurality of second pixel circuits which are located in the second display area, and a plurality of connecting lines extending from the second display area to the first display area; and
a light emitting structure layer located on a side of the circuit structure layer away from the base substrate, and comprising a plurality of first light emitting elements located in the first display area and a plurality of second light emitting elements located in the second display area;
wherein at least one first pixel circuit among the plurality of first pixel circuits is electrically connected with at least one first light emitting element among the plurality of first light emitting elements by means of at least one of the plurality of connecting lines, and is configured to drive the at least one first light emitting element to emit light; and at least one second pixel circuit among the plurality of second pixel circuits is electrically connected with at least one second light emitting element among the plurality of second light emitting elements, and is configured to drive the at least one second light emitting element to emit light; and
an orthographic projection of the plurality of connecting lines on the base substrate is not overlapped with an orthographic projection of anodes of the plurality of second light emitting elements on the base substrate.

2. The display panel according to claim 1, wherein an orthographic projection of the plurality of first pixel circuits on the base substrate is not overlapped with an orthographic projection of the plurality of first light emitting elements on the base substrate.

3. The display panel according to claim 1- or 2, wherein the orthographic projection of the plurality of connecting lines on the base substrate is a mesh pattern.

4. The display panel according to claim 1, wherein the plurality of connecting lines are made of a transparent conductive material.

5. The display panel according to claim 1, wherein in the second display area, the plurality of first pixel circuits are located on a side of the plurality of second pixel circuits away from the first display area.

6. The display panel according to claim 5, wherein the second display area is located on at least one side of the first display area along a first direction, and the plurality of first pixel circuits are located on a side of the plurality of second pixel circuits away from the first display area along the first direction.

7. The display panel according to claim 1, wherein the plurality of first pixel circuits are distributed at intervals among the plurality of second pixel circuits.

8. The display panel according to claim 1, wherein an orthographic projection of an anode of the at least one second light emitting element on the base substrate is overlapped with an orthographic projection of a second pixel circuit connected thereto on the base substrate.

9. The display panel according to claim 1, wherein in a direction perpendicular to the display panel, the circuit structure layer comprises a semiconductor layer, a first conductive layer, a second conductive layer, a third conductive layer, and a fourth conductive layer which are sequentially provided on the base substrate; and the plurality of connecting lines are located on the third conductive layer.

10. The display panel according to claim 9, wherein the plurality of first pixel circuits are located on a side of the plurality of second pixel circuits away from the first display area along the first direction; the fourth conductive layer comprises a signal line extending along a second direction; and the first direction intersects with the second direction.

11. The display panel according to claim 10, wherein the signal line of the fourth conductive layer comprises a plurality of power supply connection segments extending along the second direction; the third conductive layer comprises a power supply lap island; and adjacent power supply connection segments are electrically connected by means of the power supply lap island.

12. The display panel according to claim 9, wherein the semiconductor layer comprises active layers of transistors of the plurality of first pixel circuits and the plurality of second pixel circuits; the first conductive layer comprises gates of the transistors, and first capacitance electrode plates of storage capacitors of the plurality of first pixel circuits and the plurality of second pixel circuits; the second conductive layer comprises second capacitance electrode plates of the storage capacitors of the plurality of first pixel circuits and the plurality of second pixel circuits; and the third conductive layer comprises a plurality of lap islands configured to realize electrical connections between the transistors and electrical connections between the transistors and a signal line extending along the first direction.

13. The display panel according to claim 1, further comprising an encapsulation structure layer located on a side of the light emitting structure layer away from the base substrate, and a touch structure layer located on a side of the encapsulation structure layer away from the base substrate, the touch structure layer comprises a plurality of touch electrodes, and the plurality of touch electrodes comprise a metal mesh pattern; and
wherein an orthographic projection of the metal mesh pattern of the touch structure layer on the base substrate covers the orthographic projection of the plurality of connecting lines on the base substrate.

14. The display panel according to claim 1, wherein the orthographic projection of the plurality of connecting lines on the base substrate is not overlapped with an orthographic projection of an anode of an unconnected first light emitting element on the base substrate.

15. A display apparatus, comprising the display panel according to claim 1.

16. A preparation method of a display panel, which is used for preparing the display panel according to claim 1, wherein the method comprises:
preparing a circuit structure layer on a base substrate, the circuit structure layer comprising a plurality of first pixel circuits and a plurality of second pixel circuits which are located in a second display area, and a plurality of connecting lines extending from the second display area to a first display area, the second display area being located on at least one side of the first display area; and
preparing a light emitting structure layer on a side of the circuit structure layer away from the base substrate, the light emitting structure layer comprising a plurality of first light emitting elements located in the first display area and a plurality of second light emitting elements located in the second display area,
wherein at least one first pixel circuit among the plurality of first pixel circuits is electrically connected with at least one first light emitting element among the plurality of first light emitting elements by means of at least one of the plurality of connecting lines, and is configured to drive the at least one first light emitting element to emit light; and at least one second pixel circuit among the plurality of second pixel circuits is electrically connected with at least one second light emitting element among the plurality of second light emitting elements, and is configured to drive the at least one second light emitting element to emit light; and
an orthographic projection of the plurality of connecting lines on the base substrate is not overlapped with an orthographic projection of anodes of the plurality of second light emitting elements on the base substrate.

17. The display panel according to claim 2, wherein the orthographic projection of the plurality of connecting lines on the base substrate is a mesh pattern.

18. The display panel according to claim 2, wherein the plurality of connecting lines are made of a transparent conductive material.

19. The display panel according to claim 3, wherein the plurality of connecting lines are made of a transparent conductive material.

20. The display panel according to claim 2, wherein in the second display area, the plurality of first pixel circuits are located on a side of the plurality of second pixel circuits away from the first display area.
